(19) United States
(12) Patent Application Publication
(10) Pub. No.: US 2025/0359078 A1
(43) Pub. Date: Nov. 20, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chun-Ya Chiu, Tainan City (TW); Po-Kuang Hsieh, Kaohsiung City (TW); Chin-Hung Chen, Tainan City (TW); Ssu-l Fu, Kaohsiung City (TW); Yu-Hsiang Lin, New Taipei City (TW)

(73) Assignee: UNITED MICROELECTRONICS CORP., Hsin-Chu City (TW)

(21) Appl. No.: 18/752,717

(22) Filed: Jun. 24, 2024

(30) Foreign Application Priority Data
May 20, 2024 (TW) 113118609

(51) Int. Cl. H01L 23/522

(52) U.S. Cl. CPC H10D 1/042; H01L 23/5223; H10D 1/716

(57) ABSTRACT

A semiconductor device includes a trench, a capacitor structure and a void. The trench is formed in a substrate. The capacitor structure is disposed in the trench. The void is located in the capacitor structure. A material layer of the capacitor structure is merged in the trench to seal a top end of the void.

### BACKGROUND OF THE INVENTION

### 1. Field of the Invention

The present disclosure relates to the field of semiconductor devices, and more particularly, to a semiconductor device including a deep trench capacitor structure and a method for fabricating the same.

### 2. Description of the Prior Art

Due to capacitor structures capable of storing charges, the capacitor structures are widely applied to components of semiconductor devices such as memories. The conventional capacitor structures are planar capacitor structures. However, with the development of artificial intelligence (AI) and high performance computing (HPC), the desired capacitance value provided by the capacitor structure is increasing. In order to simultaneously satisfy the needs of AI and HPC and the trend of miniaturization of electronic components, deep trench capacitor structures gradually replaces planar capacitor structures.

However, as the desired capacitance value continues to increase, the depth of the trench also continues to be deepened, which results in an increased stress. In addition, the warpage degree of the material layer of the capacitor structure may affect the bonding effect between the capacitor structure and other film layers. Accordingly, how to improve the structure and/or the fabricating method of the deep trench capacitor structures has become an important issue for relevant industry.

### SUMMARY OF THE INVENTION

According to one aspect of the present disclosure, a semiconductor device includes a trench, a capacitor structure and a void. The trench is formed in a substrate. The capacitor structure is disposed in the trench. The void is located in the capacitor structure. A material layer of the capacitor structure is merged in the trench to seal a top end of the void.

According to another aspect of the present disclosure, a method for fabricating a semiconductor device includes steps as follows. A trench is formed in a substrate. A capacitor structure is formed in the trench, in which a material layer of the capacitor structure is merged in the trench to form a void in the trench, and the material layer seals a top end of the void.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5 and FIG. 6 are schematic cross-sectional views showing steps of a method for fabricating a semiconductor device according to an embodiment of the present disclosure.

FIG. 7, FIG. 8 and FIG. 9 are schematic cross-sectional views showing steps of a method for fabricating a semiconductor device according to another embodiment of the present disclosure.

FIG. 10 is a schematic cross-sectional view showing a semiconductor device according to yet another embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical reference signs or similar reference signs are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

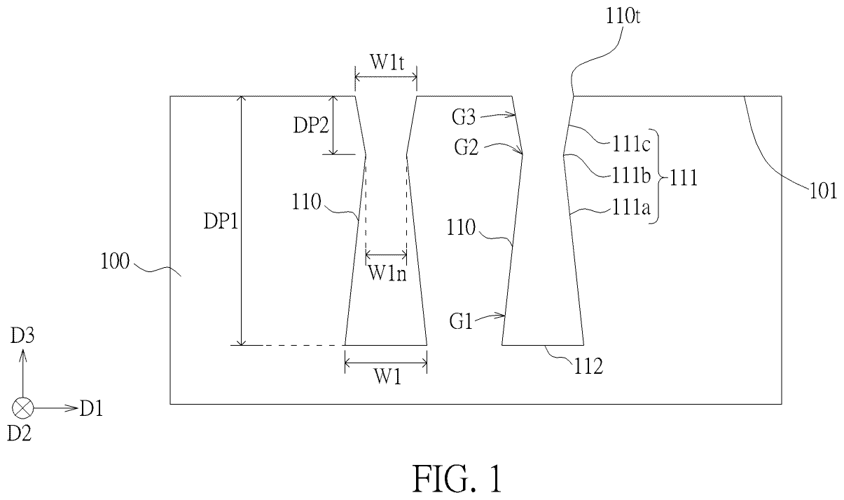

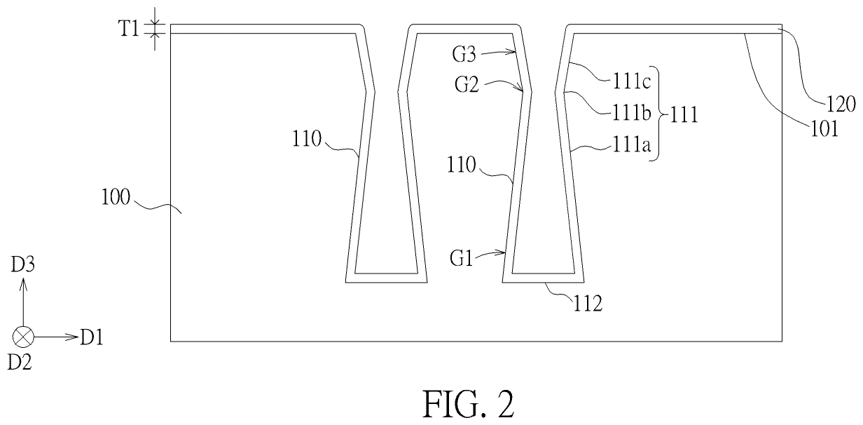

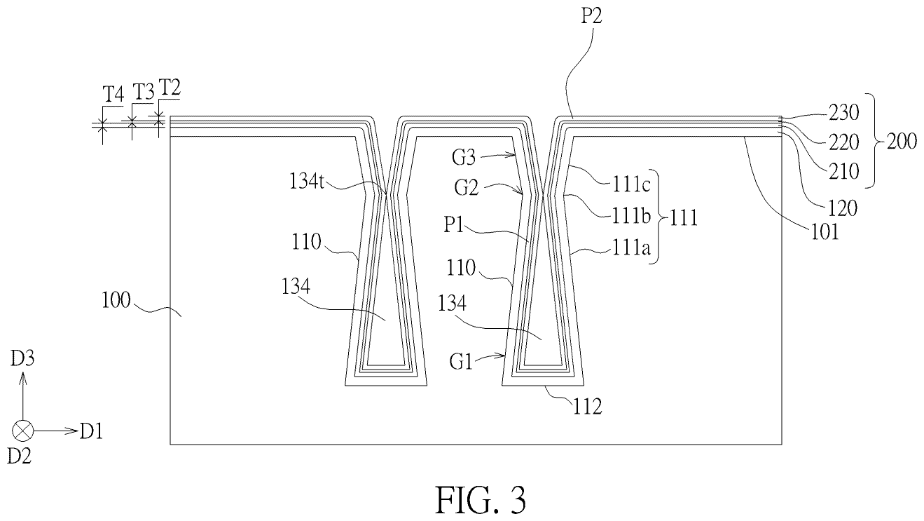

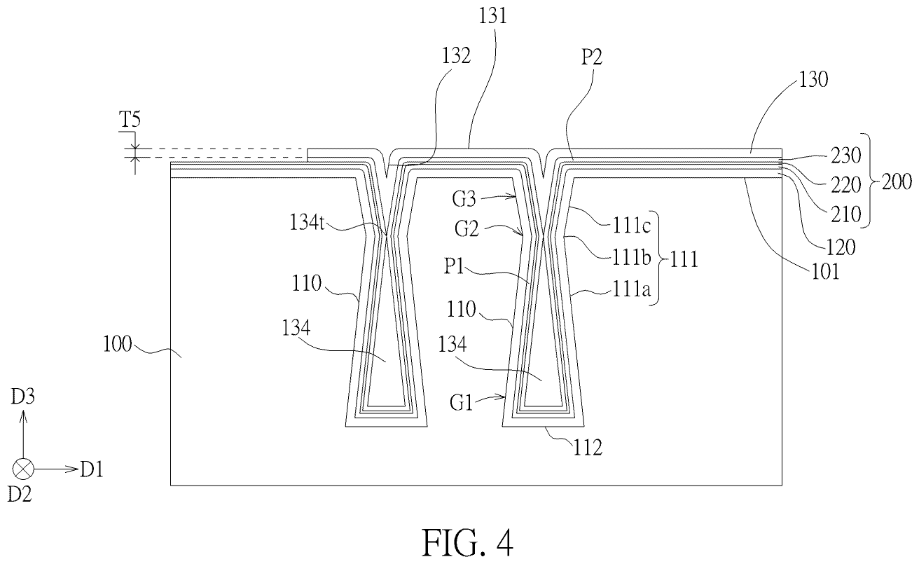

Please refer to FIG. 1 to FIG. 6, which are schematic cross-sectional views showing steps of a method for fabricating a semiconductor device 1 according to an embodiment of the present disclosure. In FIG. 1, trenches 110 are firstly formed in a substrate 100. The substrate 100 may be a silicon substrate, an epitaxial silicon substrate, a silicon carbide substrate or a silicon on insulator (SOI) substrate. The trenches 110 may be formed by semiconductor processes, such as photolithography and etching processes. The number of the trenches 110 may be one or plural. Herein, the number of the trenches 110 is exemplary two, and the two trenches 110 are adjacent to each other along the first horizontal direction D1. The number of the trenches 110 may be flexibly adjusted according to actual needs. For example, the number of the trenches 110 may be adjusted according to the desired capacitance value provided by the capacitor structure 200 formed later. The more the trenches 110, the larger the area of the capacitor structure 200, which is beneficial to increase the capacitance value of the capacitor structure 200.

The trench 110 has a width W1 in the first horizontal direction D1, the trench 110 extends along the second horizontal direction D2 and has a length (not shown) in the second horizontal direction D2. The length of the trench 110 may be greater than the width W1. The first horizontal direction D1 and the second horizontal direction D2 are perpendicular to each other.

Specifically, the trench 110 includes a bottom wall 112 and two side walls 111. The two side walls 111 are disposed at two opposite sides of the bottom wall 112 along the first horizontal direction D1. Each of the side walls 111 includes a first inclined portion 111a, a bend portion 111b and a second inclined portion 111c from bottom to top. A first trench portion G1 is defined between the two first inclined portions 111a of the two side walls 111, a neck portion G2 is defined between the two bend portions 111b of the two side walls 111, and a second trench portion G3 is defined between the two second inclined portions 111c of the two side walls 111. In other words, the trench 110 may include the first trench portion G1, the neck portion G2, and the second trench portion G3 from bottom to top. By controlling the etching conditions for forming the trenches 110, each of the trenches 110 may include the first trench portion G1, the neck portion G2, and the second trench portion G3. In the first trench portion G1, the width W1 of the trench 110 gradually decreases from bottom to top along the vertical direction D3, and the first trench portion G1 has a trapezoidal cross section (which has a narrower top and a wider bottom). In the second trench portion G3, the width W1 of the trench 110 gradually increases from bottom to top along the vertical direction D3, and the second trench portion G3 has an inverted trapezoidal cross section (which has a wider top and a narrower bottom). The neck portion G2 is the portion of the trench 110 with a smallest width (i.e., the width W1 is smallest). In other words, the two side walls 111 of the trench 110 are not vertical side walls, and the width W1 of the trench 110 varies along the vertical direction D3.

The ratio of the width W1t at the top end 110t of the trench 110 to the width W1n at the neck portion G2 of the trench 110 may range from 1.05 to 1.25. For example, the width W1t may range from 216 nanometers (nm) to 324 nm. For example, the width W1n may range from 188 nm to 282 nm. According to an embodiment of the present disclosure, the ratio of the width W1t to the width W1n may be 1.15, and the width W1n may be 235 nm.

The trench 110 has a depth DP1 in the vertical direction D3. The vertical direction D3 may be, for example, parallel to a normal direction (not shown) of the top surface 101 of the substrate 100 and perpendicular to the first horizontal direction D1 and the second horizontal direction D2. According to an embodiment of the present disclosure, the ratio of the depth DP1 to the width W1 of the trench 110 (i.e., the depth-to-width ratio) may range from 23 to 27. Since the width W1 of the trench 110 varies along the vertical direction D3, the width W1 of the aforementioned depth-to-width ratio may be based on the minimum of the width W1 of the trench 110 (i.e., the width W1n at the neck portion G2). Thereby, the trench 110 of the present disclosure has a larger depth-to-width ratio. Compared with a trench having a smaller depth-to-width ratio (such as 18 to 22), in the present disclosure, when forming the capacitor structure 200 in the subsequent process, it is beneficial to allow the material layer of the capacitor structure 200 to contact and merge at the neck portion G2, so as to form a void 134 (see FIG. 3) in the trench 110.

The neck portion G2 of the trench 110 has a depth DP2 in the vertical direction D3 (that is, the distance from the top end 110t to the neck portion G2 in the vertical direction D3). The ratio of the depth DP1 to the depth DP2 may range from 21 to 25. For example, the depth DP1 may range from 4800 nm to 7200 nm. For example, the depth DP2 may range from 208 nm to 312 nm. According to an embodiment of the present disclosure, the depth DP1 is 6000 nm, and the depth DP2 is 260 nm.

Next, as shown in FIG. 2, a liner 120 may be optionally formed in the trench 110 and on the top surface 101 of the substrate 100. The liner 120 conformally covers the bottom wall 112 and the side walls 111 of each of the trenches 110 and the top surface 101 of the substrate 100, and the liner 120 partially fills the trenches 110. The material of the liner 120 is preferably an insulating material, such as silicon oxide. The thickness T1 of the liner 120 may range from 160 angstroms to 240 angstroms.

Next, as shown in FIG. 3, a capacitor structure 200 is formed in the trenches 110, and the capacitor structure 200 partially fills the trenches 110. The capacitor structure 200 includes a first portion P1 disposed in the trenches 110 and a second portion P2 disposed on the top surface 101 of the substrate 100. Forming the capacitor structure 200 may include steps as follows. First, a bottom electrode layer 210 is formed in the trenches 110 and on the top surface 101 of the substrate 100, in which the bottom electrode layer 210 conformally covers the bottom wall 112 and the side walls 111 of each of the trenches 110 and the top surface 101 of the substrate 100 through the liner 120. Next, a high dielectric constant (high-k) dielectric layer 220 is formed on the bottom electrode layer 210, in which the high-k dielectric layer 220 conformally covers the bottom electrode layer 210. Next, a top electrode layer 230 is formed on the high-k dielectric layer 220, and the top electrode layer 230 conformally covers the high-k dielectric layer 220, in which a material layer of the capacitor structure 200 (herein, the top electrode layer 230) is merged in the trench 110 to form the void 134 in the trench 110, and the top electrode layer 230 seals the top end 134t of the void 134.

Specifically, the top electrode layer 230 is merged at the neck portion G2, and the top electrode layer 230 directly surrounds the void 134. In the process of filling material layers (herein, the liner 120, the bottom electrode layer 210, the high-k dielectric layer 220 and the top electrode layer 230) into the trenches 110, stress may be gradually accumulated in the substrate 100, which may cause the fracture of the substrate 100 or affect the performance of the capacitor structure 200. The voids 134 can buffer and absorb the stress, which may reduce the probability of the fracture of the substrate 100 and enhance the performance of the capacitor structure 200. Furthermore, the top electrode layer 230 sealing the top end 134t of the void 134 may provide the ability to adjust warpage, which is favorable for enhancing the bonding effect between the capacitor structure 200 and other film layers. Furthermore, in the embodiment, the material layer (i.e., the top electrode layer 230) of the capacitor structure 200 is used to contact and merge in the trench 110 to form the void 134 and adjust warpage. Compared with additionally forming other film layers to achieve the aforementioned function, the embodiment can further simplify the materials and the fabrication processes.

The thickness T2 of the top electrode layer 230 may be the same as the thickness T4 of the bottom electrode layer 210, but not limited thereto. The thickness T2 of the top electrode layer 230 is mainly configured to seal the top end 134t of the void 134 and provide the required ability to adjust warpage. The ratio of the thickness T2 of the top electrode layer 230 to the thickness T3 of the high-k dielectric layer 220 may range from 2.78 to 6.25. For example, the thickness T2 of the top electrode layer 230 may range from 200 angstroms to 300 angstroms, and the thickness T3 of the high-k dielectric layer 220 may range from 48 angstroms to 72 angstroms.

The materials of the bottom electrode layer 210 and the top electrode layer 230 may independently include conductive materials, such as metals of copper (Cu), chromium (Cr), titanium (Ti), tungsten (W), gold (Au), aluminum (Al), indium (In), tin (Sn), nickel (Ni), platinum (Pt), silver (Ag) or alloys thereof, but not limited thereto. According to an embodiment of the present disclosure, the materials of the bottom electrode layer 210 and the top electrode layer 230 include titanium nitride (TiN). The material of the high-k dielectric layer 220 may include a high-k dielectric material, such as a material with a dielectric constant greater than or equal to 4. The high-k dielectric layer 220 may be a single layer structure or a composite structure formed by multiple film layers. According to an embodiment of the present disclosure, the high-k dielectric layer 220 may include a nitride such as silicon nitride or a composite structure of ZrO₂/Al₂O₃/ZrO₂ (ZAZ).

Next, as shown in FIG. 4, a dielectric layer 130 is formed on the top electrode layer 230, in which the dielectric layer 130 conformally covers the top electrode layer 230 to form a recessed portion 132 above the trench 110. The recess portion 132 may have a V-shaped cross section. The dielectric layer 130 may have a thickness T5 ranging from 200 angstroms to 500 angstroms. The material of the dielectric layer 130 may include an oxide such as silicon dioxide or tetraethoxysilane (TEOS), but not limited thereto. Next, the size of the top electrode layer 230 is defined. Semiconductor processes, such as one or more photolithography and etching processes, may be performed to remove a portion of the dielectric layer 130 and a portion of the top electrode layer 230 located outside the trench 110 to expose a portion of the high-k dielectric layer 220 of the capacitor structure 200.

Next, as shown in FIG. 5, a protective layer 140 may be formed on the dielectric layer 130 and the portion of the capacitor structure 200 not covered by the dielectric layer 130. The protective layer 140 may be, for example, a contact etch stop layer (CESL). The material of the protective layer 140 may include nitride, such as silicon nitride (SiN) or silicon carbide nitride (SiCN), but not limited thereto. Specifically, after the dielectric layer 130 is formed, a planarization process such as a chemical mechanical polishing (CMP) process on the dielectric layer 130 may be omitted, and the protective layer 140 is directly formed on the dielectric layer 130 after the size of the top electrode layer 230 is defined. The recessed portion 132 of the dielectric layer 130 is reserved, and the protective layer 140 conformally covers the top surface 131 of the dielectric layer 130. The protective layer 140 may also be formed with a recessed portion 142 corresponding to the recessed portion 132, and the recessed portion 142 may also have a V-shaped cross section.

In the fabricating method including to perform a planarization process on the dielectric layer 130, when the dielectric layer 130 is first subjected to the planarization process and then other film layers (such as the protective layer 140) are formed thereon, the other film layers (such as the protective layer 140) directly covering the dielectric layer 130 are easy to peel off, and the performance of the semiconductor device 1 (see FIG. 6) may be affected or the production yield of the semiconductor device 1 may be reduced. In addition, when performing the planarization process on the dielectric layer 130, another dielectric layer (not shown) is usually required to firstly deposited on the dielectric layer 130 as a sacrificial dielectric layer to increase the total thickness (i.e., the sum of the thickness of the dielectric layer 130 and the thickness the sacrificial dielectric layer) of the dielectric layers, so that the flatness of the dielectric layer 130 after the planarization process may be improved. However, the additional deposition process requires additional materials and time, the production cost is increased thereby. In the present disclosure, by omitting the planarization process on the dielectric layer 130, the peeling probability of other film layers directly covering the dielectric layer 130 (such as the protective layer 140) can be reduced significantly. Moreover, the process can be simplified, and the costs of material and time required for depositing the sacrificial dielectric layer are omitted, which is beneficial to reduce the fabrication costs.

Next, as shown in FIG. 6, a dielectric layer 150 may be completely deposited on the substrate 100 to cover the protective layer 140. The material of the dielectric layer 150 may include oxides, such as silicon dioxide or tetraethoxysilane. Next, a plug process is performed. Specifically, semiconductor processes, such as photolithography and etching processes, may be performed to remove a portion of the dielectric layer 150, a portion of the protective layer 140, and a portion of the high-k dielectric layer 220 to form a hole 152 to expose the bottom electrode layer 210, and further semiconductor processes, such as photolithography and etching processes, are performed to remove a portion of the dielectric layer 150, a portion of the protective layer 140 and a portion of the dielectric layer 130 to form a hole 154 to expose the top electrode layer 230. Next, conductive materials are filled into the holes 152 and 154 and a planarization process is performed to form contacts CT1 and CT2 in the dielectric layer 150. The contact CT1 is electrically connected with the bottom electrode layer 210, and the contact CT2 is electrically connected with the top electrode layer 230. The conductive materials of the contacts CT1 and CT2 may be the same or different, and may independently include a barrier layer (not shown) and a metal layer (not shown). The material of the barrier layer may include titanium, tantalum, titanium nitride, tantalum nitride, nitrogen or a combination thereof. The material of the metal layer may include aluminum, titanium, tantalum, tungsten, niobium, molybdenum, copper or a combination thereof, but not limited thereto. Thereby, the fabrication of the semiconductor device 1 is completed.

Please refer to FIG. 6, which is a schematic cross-sectional view of the semiconductor device 1 according to an embodiment of the present disclosure. The semiconductor device 1 includes the trenches 110, the capacitor structure 200 and the void 134. The trenches 110 are formed in the substrate 100. The capacitor structure 200 is disposed in the trenches 110. The void 134 is located in the capacitor structure 200, in which a material layer (herein, the top electrode layer 230) of the capacitor structure 200 is merged in the trench 110 to seal the top end 134t of the void 134.

The capacitor structure 200 includes the bottom electrode layer 210, the high-k dielectric layer 220 and the top electrode layer 230. The bottom electrode layer 210 is disposed in the trenches 110 and on the top surface 101 of the substrate 100. The high-k dielectric layer 220 is disposed on the bottom electrode layer 210. The top electrode layer 230 is disposed on the high-k dielectric layer 220. The top electrode layer 230 is merged at the neck portion G2, and the top electrode layer 230 directly surrounds the void 134. The capacitor structure 200 is disposed in a the trenches 110, and thus is a deep trench capacitor structure. Compared with a planar capacitor structure, the area of the capacitor structure 200 can be increased by the depths DP1 of the trenches 110, so that a larger capacitance value can be provided.

The semiconductor device 1 may optionally further include the liner 120, the dielectric layer 130, the protective layer 140, the dielectric layer 150, and the contacts CT1 and CT2. The liner 120 is disposed in the trenches 110 and on the top surface 101 of the substrate 100, and the liner 120 is located between the substrate 100 and the capacitor structure 200. The dielectric layer 130 is disposed on the top electrode layer 230. The dielectric layer 130 may include a recessed portion 132 located above the trench 110, and the recess portion 132 may have a V-shaped cross section. The protective layer 140 is disposed on the dielectric layer 130 and a portion of the capacitor structure 200 not covered by the dielectric layer 130. The protective layer 140 may include a recessed portion 142 located above the trench 110, and the recess portion 142 may have a V-shaped cross section. The dielectric layer 150 is disposed on the protective layer 140, and the contacts CT1 and CT2 are disposed in the dielectric layer 150 and respectively electrically connected with the bottom electrode layer 210 and the top electrode layer 230. For other details about the semiconductor device 1, reference may be made to the above description, and are not repeated herein.

Please refer to FIGS. 1, 2, 7 to 9, which are schematic cross-sectional views showing steps of a method for fabricating a semiconductor device 1a according to another embodiment of the present disclosure. First, as shown in FIG. 1, trenches 110 are formed in a substrate 100. Next, as shown in FIG. 2, a liner 120 may be optionally formed in the trenches 110 and on the top surface 101 of the substrate 100.

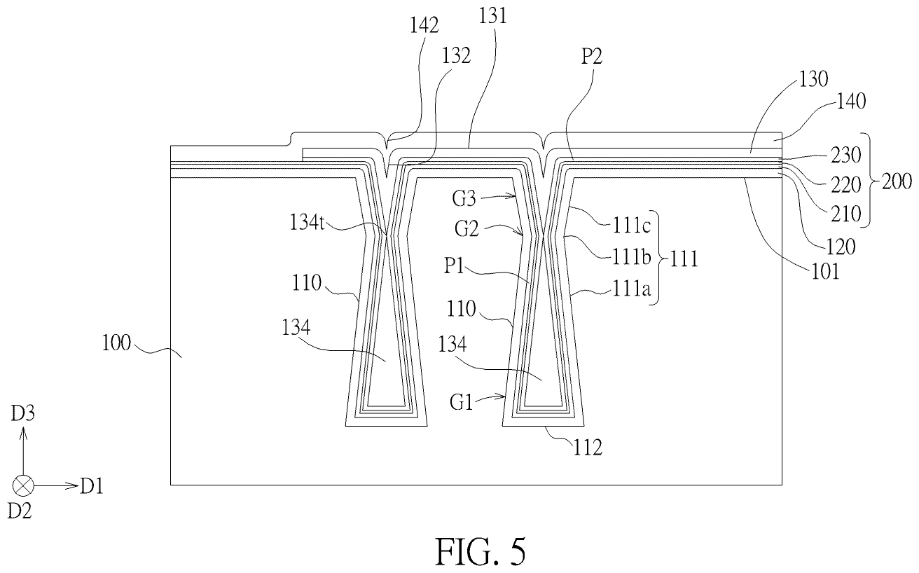

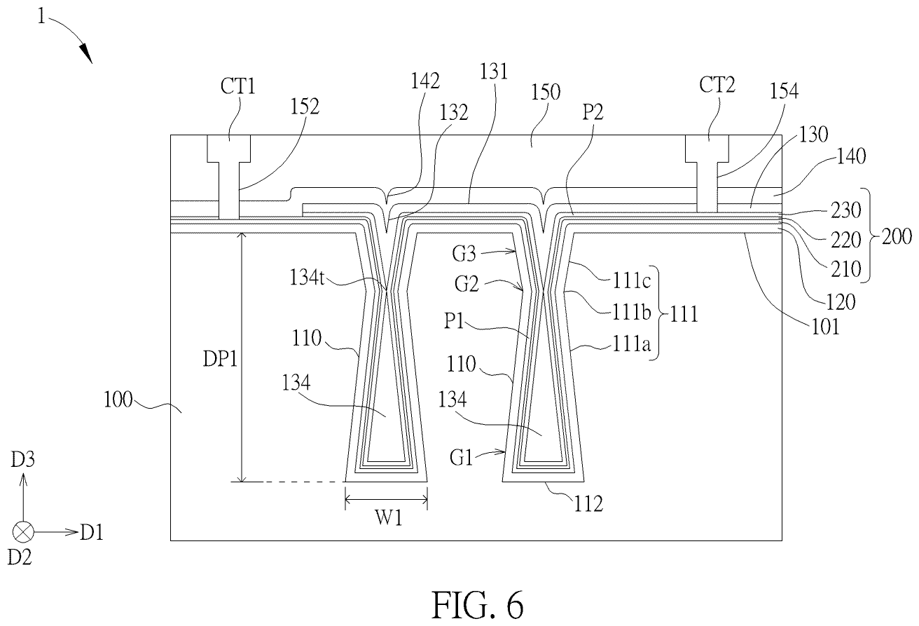

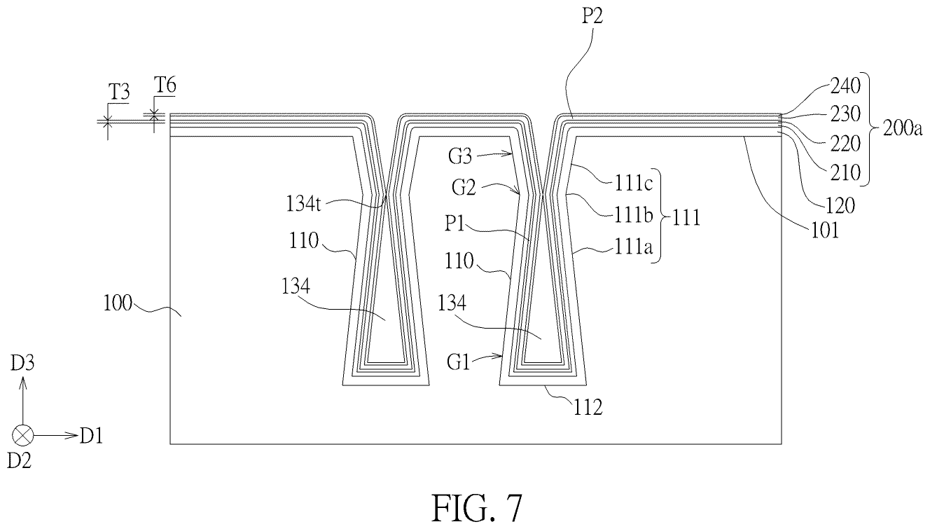

Next, as shown in FIG. 7, a capacitor structure 200a is formed in the trenches 110, and the capacitor structure 200a partially fills the trenches 110. The capacitor structure 200a includes a first portion P1 disposed in the trenches 110 and a second portion P2 disposed on the top surface 101 of the substrate 100. Forming the capacitor structure 200a may include steps as follows: a bottom electrode layer 210 is formed in the trenches 110 and on the top surface 101 of the substrate 100, a high-k dielectric layer 220 is formed on the bottom electrode layer 210, a top electrode layer 230 is formed on the high-k dielectric layer 220, and a high-k dielectric layer 240 is formed on the top electrode layer 230. The high-k dielectric layer 240 conformally covers the top electrode layer 230, in which a material layer (herein, the high-k dielectric layer 240) of the capacitor structure 200a is merged in the trench 110 to form a void 134 in the trench 110, and the high-k dielectric layer 240 seals the top end 134t of the void 134.

In the embodiment, the capacitor structure 200a includes two high-k dielectric layers 220 and 240, in which the high-k dielectric layer 220 is disposed between the bottom electrode layer 210 and the top electrode layer 230, and is configured for electrically insulating the bottom electrode layer 210 and the top electrode layer 230. The high-k dielectric layer 240 is configured for forming the voids 134 in the trench 100 and for providing the function of adjusting warpage, so as to enhance the bonding effect between the capacitor structure 200a and other film layers.

Specifically, the high-k dielectric layer 240 is merged at the neck portion G2, and the high-k dielectric layer 240 is merged at the neck portion G2 after the high-k dielectric layer 240 filling into the first trench portion G1 and completely covering the bottom wall 112 and the two side walls 111 of the first trench portion G1 of the trench 110. Therefore, the high-k dielectric layer 240 directly surrounds the void 134. Moreover, in the trench 110, the high-k dielectric layer 240 is disposed between the top electrode layer 230 and the void 134. With the void 134 having the function of buffering and absorbing the stress, the probability that the substrate 100 fractures may be reduced and the performance of the capacitor structure 200a may be enhanced. With the high-k dielectric layer 240 sealing the top end 134t of the void 134, the ability to adjust warpage may be provided, which is favorable for enhancing the bonding effect between the capacitor structure 200a and other film layers.

The thickness T6 of the high-k dielectric layer 240 may be the same as the thickness T3 of the high-k dielectric layer 220, but not limited thereto. The thickness T6 of the high-k dielectric layer 240 is mainly configured to seal the top end 134t of the void 134 and provide the required ability to adjust warpage. The ratio of the thickness T2 (see FIG. 3) of the top electrode layer 230 to the thickness T6 of the high-k dielectric layer 240 may range from 2.78 to 6.25. For example, the thickness T2 of the top electrode layer 230 may range from 200 angstroms to 300 angstroms, and the thickness T6 of the high-k dielectric layer 240 may range from 48 angstroms to 72 angstroms.

The material of the high-k dielectric layer 240 may include a high-k dielectric material, such as a dielectric material with a dielectric constant greater than or equal to 4. The high-k dielectric layer 240 may be a single layer structure or a composite structure formed by multiple film layers. According to an embodiment of the present disclosure, the high-k dielectric layer 240 may include a nitride such as silicon nitride or a composite structure of ZrO₂/Al₂O₃/ZrO₂ (ZAZ). The material of the high-k dielectric layer 220 may be the same as the material of the high-k dielectric layer 240. Thereby, the types of the materials and the processes required for fabricating the capacitor structure 200a may be simplified. By using the material layer (i.e., the high-k dielectric layer 240) of the capacitor structure 200a to contact and merge in the trench 110 to form the void 134 and adjust warpage, the embodiment can further simplify materials and fabrication processes compared with additionally forming other film layers to achieve the aforementioned function. For other details about the capacitor structure 200a, reference may be made to the relevant description about the capacitor structure 200 above.

Next, as shown in FIG. 8, a dielectric layer 130 is formed on the high-k dielectric layer 240. Next, the size of the top electrode layer 230 is defined. Semiconductor processes, such as one or more photolithography and etching processes, may be performed to remove a portion of the dielectric layer 130, a portion of the high-k dielectric layer 240 and a portion of the top electrode layer 230 located outside the trench 110 to expose a portion of the high-k dielectric layer 220 of the capacitor structure 200a.

Next, as shown in FIG. 9, a protective layer 140 may be formed on the dielectric layer 130 and the portion of the capacitor structure 200a not covered by the dielectric layer 130. After forming the dielectric layer 130 and before forming the protective layer 140, a planarization process such as a CMP process on the dielectric layer 130 may be omitted, so that the recessed portion 132 of the dielectric layer 130 is reserved, and the protective layer 140 may also be formed with a recessed portion 142 corresponding to the recessed portion 132. Next, a dielectric layer 150 may be completely deposited on the substrate 100 to cover the protective layer 140, and a plug process may be performed to form the contacts CT1 and CT2 in the dielectric layer 150. Thereby, the fabrication of the semiconductor device 1a is completed.

The main difference between the semiconductor device la and the semiconductor device 1 is that the structure of the capacitor structure 200a is different from that of the capacitor structure 200. In the capacitor structure 200, the top electrode layer 230 is merged at the neck portion G2 to form the void 134 in the trench 110. Compared with the capacitor structure 200, the capacitor structure 200a further includes the high-k dielectric layer 240. In the capacitor structure 200a, the high-k dielectric layer 240 is merged at the neck portion G2 to form the void 134 in the trench 110. For other details about the semiconductor device 1a, reference may be made to the relevant description about the semiconductor device 1 above, and are omitted herein.

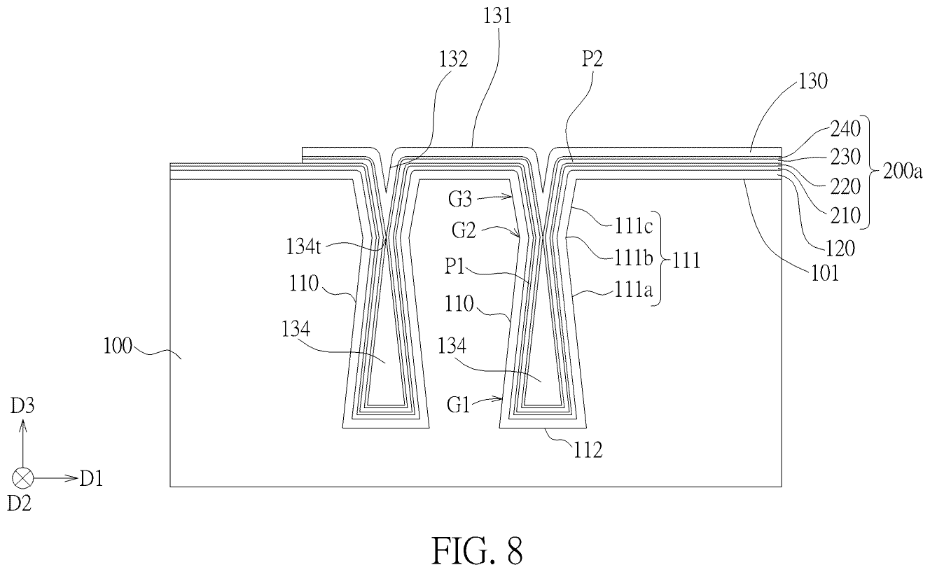

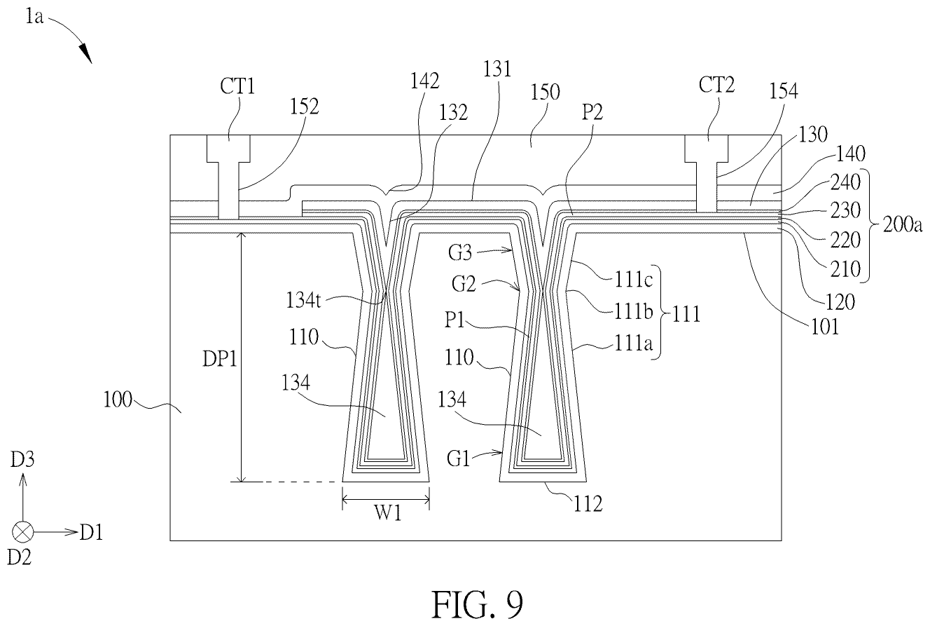

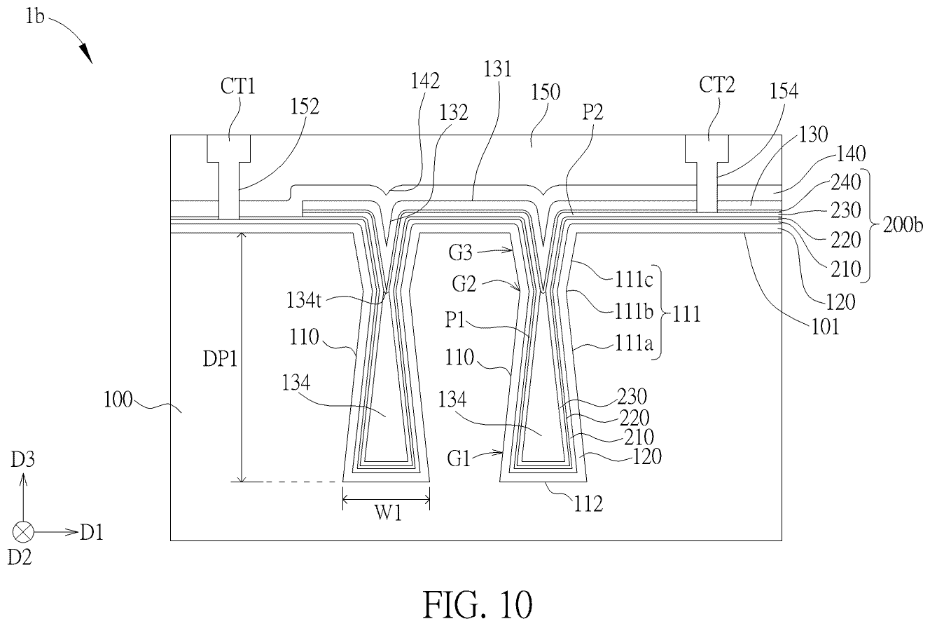

Please refer to FIG. 10, which is a schematic cross-sectional view showing a semiconductor device 1b according to yet another embodiment of the present disclosure. The main difference between the semiconductor device 1b and the semiconductor device 1a is that the structure of the capacitor structure 200b is different from that of the capacitor structure 200a. Compared with the capacitor structure 200a, the high-k dielectric layer 240 is merged at the neck portion G2 before filling into the first trench portion G1. Therefore, in the embodiment, the high-k dielectric layer 240 seals the top end 134t of the void 134, and the top electrode layer 230 directly surrounds the void 134. Herein, the top electrode layer 230 directly surrounds the portion of the void 134 other than the top end 134t of the void 134, such as the bottom surface and the side surface of the void 134, but not limited thereto. In other embodiment, the high-k dielectric layer 240 can be merged at the neck portion G2 after filling into the first trench portion G1 but not completely covering the bottom wall 112 and the side walls 111 of the first trench portion G1. In other words, the high-k dielectric layer 240 does not cover, partially covers, or completely covers the bottom wall 112 and the side walls 111 of the first trench portion G1 of the trench 110 all fall within the scope of the present disclosure. For other details about the semiconductor device 1b, reference may be made to the relevant description about the semiconductor device 1 and 1a above, and are omitted herein.

The aforementioned film layers, such as the liner 120, the bottom electrode layer 210, the high-k dielectric layers 220 and 240, the top electrode layer 230, the dielectric layer 130, the protective layer 140, the dielectric layer 150 and the contacts CT1 and CT2, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

Compared with the prior art, in the method for fabricating the semiconductor device, with the material layer of the capacitor structure being merged in the trench to form a void in the trench, and the material layer sealing the top end of the void, it is beneficial to reduce the stress, so that the probability that the substrate fractures can be reduced, the performance of the capacitor structure can be enhanced, and the service life of the capacitor structure can be extended. Furthermore, the material layer sealing the top end of the void can provide the ability to adjust warpage, which is beneficial to improve the bonding effect between the capacitor structure and other film layers, so as to improve the yield and performance of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a trench formed in a substrate;
a capacitor structure disposed in the trench; and
a void located in the capacitor structure, wherein a material layer of the capacitor structure is merged in the trench to seal a top end of the void.

2. The semiconductor device of claim 1, wherein the capacitor structure comprises:
a bottom electrode layer disposed in the trench and on a top surface of the substrate;
a first high dielectric constant dielectric layer disposed on the bottom electrode layer; and
a top electrode layer disposed on the first high dielectric constant dielectric layer, wherein the top electrode layer is the material layer of the capacitor structure.

3. The semiconductor device of claim 2, wherein the top electrode layer directly surrounds the void.

4. The semiconductor device of claim 1, wherein the capacitor structure comprises:
a bottom electrode layer disposed in the trench and on a top surface of the substrate;
a first high dielectric constant dielectric layer disposed on the bottom electrode layer;
a top electrode layer disposed on the first high dielectric constant dielectric layer; and
a second high dielectric constant dielectric layer disposed on the top electrode layer, wherein the second high dielectric constant dielectric layer is the material layer of the capacitor structure.

5. The semiconductor device of claim 4, wherein a dielectric constant of the second high dielectric constant dielectric layer is greater than or equal to 4.

6. The semiconductor device of claim 4, wherein a material of the first high dielectric constant dielectric layer is the same as a material of the second high dielectric constant dielectric layer.

7. The semiconductor device of claim 4, wherein the top electrode layer directly surrounds the void.

8. The semiconductor device of claim 4, wherein the second high dielectric constant dielectric layer is disposed between the top electrode layer and the void.

9. The semiconductor device of claim 4, wherein a thickness of the top electrode layer to a thickness of the second high dielectric constant dielectric layer ranges from 2.78 to 6.25.

10. The semiconductor device of claim 1, wherein the trench comprises a neck portion, the neck portion is a portion of the trench with a smallest width, and the material layer of the capacitor structure is merged at the neck portion.

11. A method for fabricating a semiconductor device, comprising:
forming a trench in a substrate; and
forming a capacitor structure in the trench, wherein a material layer of the capacitor structure is merged in the trench to form a void in the trench, and the material layer seals a top end of the void.

12. The method of claim 11, wherein forming the capacitor structure in the trench comprises:
forming a bottom electrode layer in the trench and on a top surface of the substrate;
forming a first high dielectric constant dielectric layer on the bottom electrode layer; and
forming a top electrode layer on the first high dielectric constant dielectric layer, wherein the top electrode layer is the material layer of the capacitor structure.

13. The method of claim 12, wherein the top electrode layer directly surrounds the void.

14. The method of claim 11, wherein forming the capacitor structure in the trench comprises:
forming a bottom electrode layer in the trench and on a top surface of the substrate;
forming a first high dielectric constant dielectric layer on the bottom electrode layer;
forming a top electrode layer on the first high dielectric constant dielectric layer; and
forming a second high dielectric constant dielectric layer on the top electrode layer, wherein the second high dielectric constant dielectric layer is the material layer of the capacitor structure.

15. The method of claim 14, wherein a dielectric constant of the second high dielectric constant dielectric layer is greater than or equal to 4.

16. The method of claim 14, wherein a material of the first high dielectric constant dielectric layer is the same as a material of the second high dielectric constant dielectric layer.

17. The method of claim 14, wherein the top electrode layer directly surrounds the void.

18. The method of claim 14, wherein the second high dielectric constant dielectric layer is disposed between the top electrode layer and the void.

19. The method of claim 14, wherein a thickness of the top electrode layer to a thickness of the second high dielectric constant dielectric layer ranges from 2.78 to 6.25.

20. The method of claim 11, wherein the trench comprises a neck portion, the neck portion is a portion of the trench with a smallest width, and the material layer of the capacitor structure is merged at the neck portion.
